(19) United States
(12) Patent Application Publication
(10) Pub. No.: US 2025/0167197 A1
(43) Pub. Date: May 22, 2025

(54) PROCESS FOR PRE-LITHIATION AND EQUIPMENT FOR IMPLEMENTING THE SAME

(71) Applicant: ULVAC, INC., Kanagawa (JP)

(72) Inventors: Akiyoshi SUZUKI, Kanagawa (JP); Sichen JIN, Kanagawa (JP); Xinping QIU, Hebei (CN)

(73) Assignee: ULVAC, INC., Kanagawa (JP)

(21) Appl. No.: 18/942,842

(22) Filed: Nov. 11, 2024

(30) Foreign Application Priority Data
Nov. 17, 2023 (CN) 202311652253.2

(51) Int. Cl. H01M 4/04; C23C 14/14; C23C 14/24; C23C 14/58; H01M 4/02; H01M 4/1393; H01M 4/62

(52) U.S. Cl. CPC H01M 4/0423; C23C 14/14; C23C 14/24; C23C 14/5806; C23C 14/5833; C23C 14/586; H01M 4/0471; H01M 4/1393; H01M 4/62; H01M 2004/021; H01M 2004/027

(57) ABSTRACT

The present disclosure relates to a process for pre-lithiation and an equipment for implementing the same. The process for pre-lithiation comprising evaporating lithium onto a surface of a negative electrode to form a lithium layer thereon and subjecting the negative electrode to a thermal treatment.

This application claims priority under 35 U.S.C. § 119 to Chinese Patent Application No. 202311652253.2, filed on Nov. 17, 2023, which is incorporated by reference.

### TECHNICAL FIELD

This invention relates to a process of deposition of lithium onto surface of negative electrode of a battery before assembly of the battery and an equipment for implementing the same.

### BACKGROUND

In recent years, a secondary battery as an energy storage technology using lithium or other alkali metals has been attracting attention. Storage and release of energy is performed during charging and discharging of the battery, but intercalation and de-intercalation of alkali metals are not completely reversible, and thus capacity of the battery decreases with charge/discharge cycles depending on the irreversible reaction that occurs.

To solve this problem, a technology called pre-lithiation has been proposed in the manufacturing process of lithium-ion batteries.

Pre-lithiation is a process of adding lithium into a negative electrode of a battery before its manufacturing is completed, and can improve energy density of the battery and extend its cycle life. Irreversible capacity is a capacity of lithium consumed by formation of a solid electrolyte interlayer (SEI) on the negative electrode, mainly due to decomposition of electrolyte during initial charging, and SEI formation cannot be avoided in secondary lithium batteries.

Here, a technology using physical vapor deposition (PVD) is a superior production method in the area of thin film and is expected as a method to improve energy density of lithium ion batteries because it can precisely control an amount of lithium required for pre-lithiation without suffering from being affected by moisture and oxygen since deposition of lithium is completed in vacuum. This method is expected to improve energy density of the lithium-ion batteries.

However, reaction efficiency of pre-lithiation is concerned with structure of an electrode. Given there is no electrolyte before assembly of a battery, diffusion path of lithium is contact points between active material of the electrode, and thus performance of the pre-lithiation is affected by density of the electrode. Furthermore, in the assembly process after pre-lithiation, the electrode, the surface of active materials of which is unstable since it is covered with a lithium film or reacted with lithium, is generally handled in a dry room but is affected by moisture and oxygen, thus reducing effectiveness of pre-lithiation.

At present, various pre-lithiation methods have been reported, but due to their respective shortcomings, large-scale commercial applications have not yet been achieved.

### SUMMARY OF INVENTION

### Technical Problem

In view of the above problems, in particular that reaction efficiency of pre-lithiation is dependent on the structure (e.g. press density) of active material of the negative electrode and that pre-lithiated negative electrode is unstable and is susceptible against atmospheric ambient (O₂ and less H₂O in dry air) before assembly of the lithium-ion batteries, the present invention has been completed.

The present invention aims to provide a process of pre-lithiation that is carried out at a high reaction efficiency and if necessary can form a passivation layer for stabilization of electrode surface, and an equipment for implementing the process.

### Technical Solution

One aspect of the present invention provides a pre-lithiation process, which comprises evaporating lithium onto a surface of a negative electrode to form a lithium layer thereon and subjecting the negative electrode to a thermal treatment.

Another aspect of the present invention provides an equipment for implementing the pre-lithiation process.

### Advantageous Effects

The present invention can provide a process of pre-lithiation that is carried out at a high reaction efficiency and if necessary can form a passivation layer for stabilization of electrode surface, and an equipment for implementing the process.

### BRIEF DESCRIPTION OF DRAWINGS

The following drawings appended to the present specification are intended to illustrate exemplary embodiments of the present invention, and the spirit of the present invention will be more clearly understood from the accompanying drawing together with the following description of the invention, and thus illustrations in the drawing should not be construed as limiting the scope of the present invention.

FIG. 1 is a scattered diagram showing correlation of ICE with thickness of Li film in Examples.

FIG. 2 is a process diagram showing, from left to right, Examples, Comparative Examples without formation of a protection layer, and Comparative Examples without formation of a protection layer and thermal treatment.

FIG. 3 is a diagram illustrating activation (heating) treatment.

FIG. 4 is a diagram showing SEM images of cross sections of graphite (1) with a press density of about 1.61 g/cm³, graphite (2) with a press density of about 1.29 g/cm³, and SiO/C with a press density of about 1.16 g/cm³ (magnification: graphite (1), (2)×5K, SiO/C×3K).

FIG. 5 is a diagram showing surface roughness of each of graphite (1), graphite (2), and SiO/C, wherein Ra refers to arithmetic average roughness and Rz refers to ten-point average roughness.

FIG. 6 is a layout of device for mass production, and FIG. 7 is another layout of device for mass production, wherein number 1 refers to reaction chamber, number 2 refers to heating and winding chamber, number 3 refers to unwinding chamber, and number 4 refers to evaporation chamber.

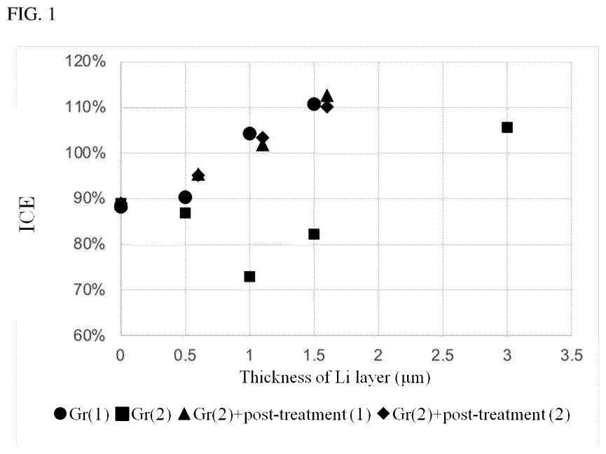

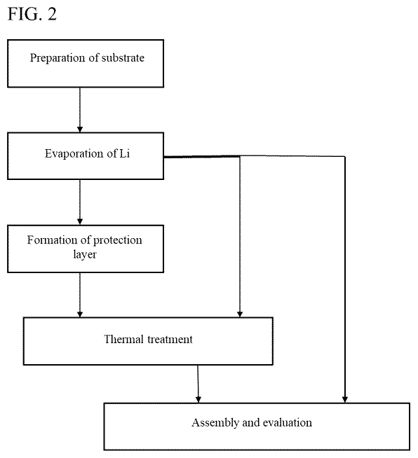

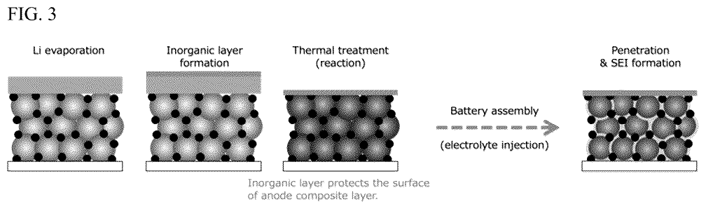

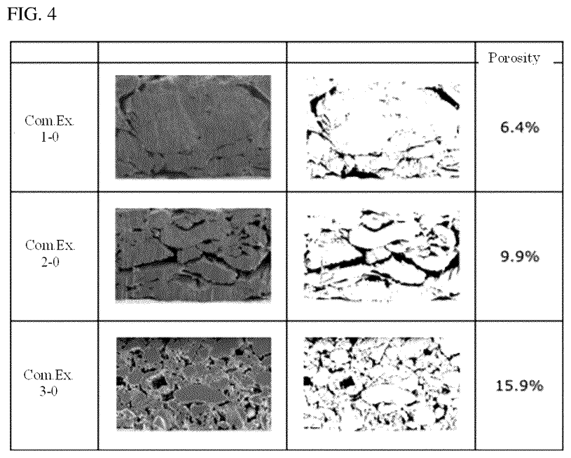

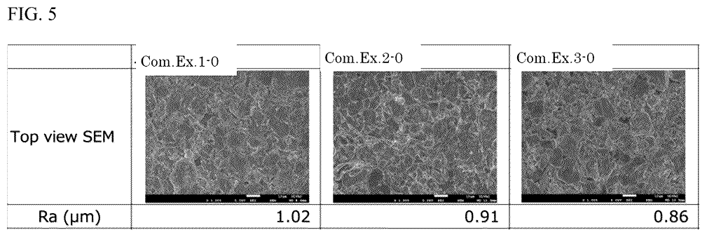

### DETAILED DESCRIPTION

The pre-lithiation process of this invention comprises forming a lithium layer and conducting a thermal treatment. The pre-lithiation process of this invention further comprises forming a surface protection layer between forming the lithium layer and conducting the thermal treatment.

### <A: Formation of a Lithium Layer>

Deposition system consists of a glove box, a transport chamber, and a deposition chamber. Target substrate of anode was placed on a sample holder in the glove box with an argon atmosphere with a dew point of −50° C. or lower, and was transported to the deposition chamber through the transport chamber. In order to obtain a high-quality lithium deposition film, the vacuum in the deposition chamber was set to be less than 1E-4 Pa for the partial pressures of H₂O and O₂. Lithium metal placed in the crucible in the deposition chamber was heated by a lamp heater, and the lithium deposition process was carried out while rotating the sample holder. The deposition rate and thickness were controlled using a thickness monitor with a quartz crystal microbalance (QCM). The deposition rate was set to 50 Å/sec and the thickness to a specified value.

### <B: Formation of Surface Protective Layer>

### B-1: Using Nitrogen Gas

Lithium nitride was formed on the surface of lithium layer by introducing nitrogen gas while rotating the substrate holder in the reaction chamber and maintaining the pressure at 150 Pa. A layer of lithium nitride with a thickness of 100 nm was formed in 10 min.

### B-2: Using Nitrogen Active Species (e.g., Ion Source)

Nitrogen gas was introduced while the substrate holder in the deposition chamber was rotated, and nitrogen active species (ions and radicals) were irradiated to the substrate using an ion source unit (eH400 manufactured by KRI) under conditions of a discharge voltage (Vf) of 150 V and a discharge current (If) of 1.0 A. The pressure during discharge was about 1E-2 Pa, and the distance between the emission source and the substrate was 200 mm. A layer of lithium nitride of about 100 nm was formed in 1 minute.

### <C: Heat Treatment>

After the surface protection layer was formed, the deposition chamber was evacuated to 1E-4 Pa or lower, and the substrate to be treated was heated to 130° C. using an infrared lamp heater to activate the pre-lithiation reaction. Considering thermal damage to the binder compound in the negative electrode, a treatment temperature of 130° C. or lower is desirable.

Water-based binders are used from the viewpoint of cost and environmental load. Specifically, the styrene-butadiene rubber (SBR) based binder and polyacrylic acid (PAA) based binder have heat resistance temperatures of 150° C. and 130° C. respectively.

In addition to copper foil, a composite current collector with a copper thin film on both sides of a resin film may be used for the negative electrode current collector, and the temperature should be considered depending on material of the resin film.

Regarding specific materials of the resin film and their heat resistance temperatures, polypropylene (PP) is 120° C. to 160° C., polyethylene terephthalate (PET) is 150° C., polyethylene naphthalate (PEN) is 180° C., polyethylene sulfide (PPS) is 200 to 240° C., and polyimide (PI) is 300° C. or higher. However, PP and PET are more practical (and actually used) from a cost standpoint.

In addition, a melting point of the lithium metal is 180° C., so it cannot be processed at a temperature higher than 175° C., for example.

Meanwhile, a treatment temperature of 80° C. or higher is necessary to exceed diffusion barrier between grains of active material of the negative electrode since there is no Li-ion conductive electrolyte in the electrode. Especially in case of a low-density electrode, if the treatment temperature is low, it will not exceed the diffusion barrier between grains, and Li will stay in the holes and be inactivated, so the Li needed to form SEI cannot spread all over the electrode.

The surface protection layer has a thickness of from 20 nm to 2000 nm depending on roughness of surface on which it is formed. In the surface treatment using N₂ gas, a uniform protective layer can be formed no matter whether the surface to be treated is rough or thin, but the reaction speed is slow. In the surface treatment using plasma (ion), it is difficult to form a uniform protective film when the surface is rough, especially in the part with a shape on its surface, so a thick film is needed to form a film with high protective performance. However, due to the use of plasma, the reaction speed is very fast. The minimum film thickness for obtaining protective performance needs to be at least 20 nm, and since the surface roughness Ra of the negative electrode is about 1.0 μm, so the maximum film thickness is considered to be 2000 nm.

The surface protection layer comprises Li₃N.

The surface protection layer is formed in a section that maintains a span longer than a main roller when viewed horizontally or vertically, and a conveying speed is from 1 m/min to 20 m/min.

The surface protection layer is formed in an atmosphere containing nitrogen gas or by irradiation with nitrogen ions.

The thermal treatment is carried out in an annealing room configured with a preheating mechanism and a winding roller with thermal control.

The lithium layer has a thickness of 0.5 μm to 10 μm, preferably 0.5 μm to 6 μm, and more preferably 0.5 μm to 2 μm.

An active material in the negative electrode comprises or consists of natural or artificial graphite, silicon, silicon oxide SiOₓ (0.53×≤1.5), or a combination thereof.

The thermal treatment is carried out at a temperature of from 80° C. to 130° C. in an atmosphere of rare gases or in an ambient atmosphere.

The thermal treatment is maintained at 80° C. for at least 6 minutes when the negative electrode has a press density of 1.3 g/cm³ to 1.6 g/cm³.

The thermal treatment is maintained at 130° C. for at least 90 minutes when the negative electrode has a press density of 1.0 to 1.3 g/cm³.

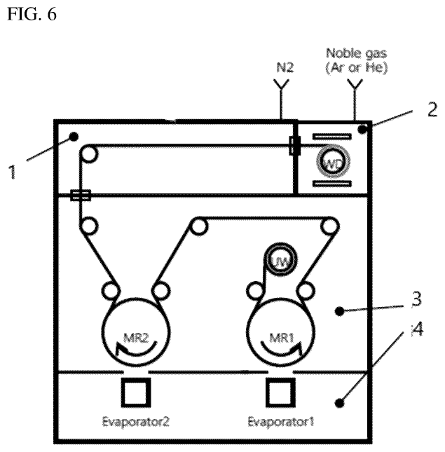

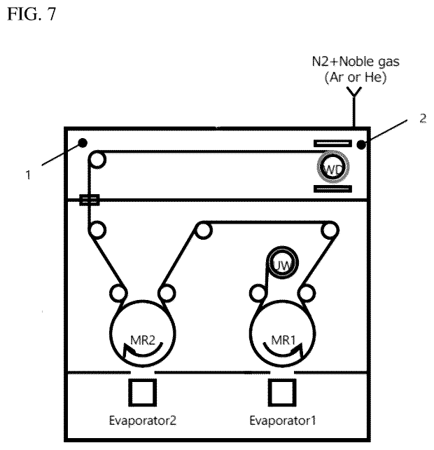

In addition, the pre-lithiation process of this invention can be carried out in the device as shown in FIG. 6 or FIG. 7. In FIG. 6, formation of surface protective layer is conducted in a reaction chamber 1 and then thermal treatment is carried out in a heating and winding chamber 2 filled with noble gas. In FIG. 7, N₂ and noble gas are introduced simultaneously to carry out formation of surface protective layer and thermal treatment. As a result, thermal conduction between layers is improved by heating in a higher pressure atmosphere.

The film is deposited on the main roller in the unwinding chamber 3. It should be clearly stated that the unwinding chamber 3 has a function to roll out a web.

When the surface protective layer is formed by gas reaction or plasma reaction, in order to carry out surface treatment at a relatively fast speed of film conveying, winder and unwinder rollers are arranged on the same side, thus becoming an advantageous device with a small footprint.

The wall surface of the chamber adjacent to number 1 has a path, which should be an opening (not shown), for inflow or outflow of the web.

The heating and winding chamber 2 has heater elements as panel heaters shown in.FIG. 6 and FIG. 7. The panel heater which is in rectangular shape and is located above and below the winder is configured to be temperature-controlled by an electric power or a cooling medium.

In the center of the winder of the heating and winding chamber 2, there is a shaft (not shown) that applies tension to the web and enables the web to be transported and rewound. A similar shaft also exists in the center of unwinder of the unwinding chamber 3.

There is a main-roller directly above the evaporators in the unwinding chamber 3. Each main-roller is configured so that a web can be conveyed at a speed that enables deposition after providing a necessary tension to the web in cooperation with the shaft.

N₂ and noble gases should be introduced into the heating and winding chamber 2 with the dew point of the atmosphere being controlled, for example, below −50° C. as mentioned above. This will limit production of the amount of H₂O involved in the Li₃N film, and will also allow for the reaction and the heat treatment to be faster. The noble gas should be inert to Li, and typically is a rare gas.

It is preferable to provide a differential pumping mechanism at the opening. This is because the differential pumping mechanism prevents the inflow of nitrogen into the unwinding chamber 3 to maintain a purity of the Li layer, which is an evaporated film, and also makes it possible to increase the nitrogen partial pressure of the reaction chamber 1 compared to the unwinding chamber 3, enabling a faster nitridation (Li₃N) reaction to be obtained. This result allows for a smaller footprint.

The shaft in the winder section can be given a heater function as in the heating and winding chamber 2. As a result, the web wound in the shape of coil in the winder section can have a cooling and heating source not only on the surface side but also on the core side. In other words, the web can be heated not only on the outside but also on the inside of the coil, which is a three-dimensional shape, and thus each layer of the web that makes up the coil can take a uniform temperature, which enables uniform heat treatment.

### Mode for Carrying Out the Invention

### EXAMPLES

Hereinafter, the present invention will be described in more detail with reference to examples and experimental examples, but the present invention is not limited by these examples and experimental examples. The examples of the present invention may be modified into various forms, and the scope of the present invention should not be construed as being limited to the examples described in detail below. The examples of the present invention are provided to more fully describe the present invention to those skilled in the art.

### Example 1

### A: Preparation of Negative Electrode Sheet

The negative electrode sheet was prepared by coating the surface of a copper foil as current collector with the following active material slurry, followed by steps of heating, drying and calendaring.

The active material slurry is composed of graphite (1) as an active material, styrene butadiene rubber (SBR) and carboxymethyl cellulose (CMC) as binders, and carbon black as a conductivity aid. A coated film was formed on one side of the copper foil with a thickness of 9 μm. Press density of the electrode was calculated to be 1.609 g/cm³ after measuring thickness and weight of the electrode.

Graphite (1) with a capacity density of ≥300 mAh/g was purchased from Shenzhen Kejing Star Technology Co.

### B: Formation of Lithium Layer

No lithium layer was formed on the surface of the negative electrode in Comparative Example 1-0. A lithium layer with a thickness of 0.5 μm, 1.0 μm, 1.5 μm, 1.0 μm, or 1.0 μm was formed via evaporation in vacuum of a lithium metal onto the surface of the negative electrode in Comparative Example 1-1, Comparative Example 1-2, Comparative Example 1-3, Comparative Example 1-4, or Comparative Example 1-5 respectively.

### C: Formation of Surface Protective Layer

No surface protection layer was formed in Comparative Example 1-0 to Comparative Example 1-5.

### D: Thermal Treatment

Thermal treatment was not implemented in Comparative Example 1-0 to Comparative Example 1-3. Thermal treatments as shown in Table 1 were implemented in Comparative Example 1-4 and Comparative Example 1-5.

### Evaluation Process on Battery Performance

### <Preparation of Half Battery (Half Cell)>

The negative electrodes as prepared in Comparative Example 1-0 to Comparative Example 1-5 each were cut into a size of 14 mm in diameter and used as a working electrode, and a lithium foil (with a thickness of 50 μm) was cut to a size of 16 mm in diameter and used as a positive electrode. An electrolyte was obtained by dissolving LiPF₆ into a mixture of ethylene carbonate (EC) and diethyl carbonate (DEC) (with a mixing ratio being 50:50, and both of them being purchased from DoDo Chem. Inc.) at a concentration of 1 mol/L. A porous material made of polypropylene (Celgard: #2325) was used as a separator. Thus, a half battery was prepared.

### <Evaluation of Performance of Half Battery>

Initial discharging was conducted at a constant current of C/10 (wherein 1 C represents a current at which a battery can be fully discharged in one hour) until a cut-off voltage of 0.01 V was reached. Initial charging was conducted at a constant low current of C/10 until a cut-off voltage of 1.5 V was reached. Initial coulombic efficiency (ICE) of a half battery was evaluated and obtained according to the following formula:

ICE(%)=(initial charge capacity/initial discharge capacity)×100

Results of evaluation in Comparative Example 1-0 to Comparative Example 1-5 are shown in Table 1. It can be seen from Comparative Example 1-0 to Comparative Example 1-3 that when a material of negative electrode with a high press density such as 1.609 g/cm³ is used, ICE is increased with an increase of thickness of the lithium layer. ICE of 104.2% in Comparative Example 1-2 was obtained with a thickness of the lithium layer being 1.0 μm, which is close to a theoretical value corresponding to an ICE of 100%, even without thermal treatment. Furthermore, it can be seen from Comparative Example 1-4 to Comparative Example 1-5 that the thermal treatment has no significant influence on ICE.

### Example 2

### A: Preparation of Negative Electrode Sheet

The negative electrode sheet was prepared in the same manner as EXAMPLE 1 except that graphite (2) was used as an active material of the negative electrode.

The graphite (2) with a capacity density of ˜330 mAh/g was purchased from Hefei Kejing Material Technology Co.

The negative electrode thus obtained has a press density of 1.285 g/cm³.

### B: Formation of Lithium Layer

No lithium layer was formed on the surface of the negative electrode in Comparative Example 2-0. A lithium layer with a thickness of 0.5 μm, 1.0 μm, 1.5 μm, or 3.0 μm was formed via evaporation in vacuum of a lithium metal onto the surface of the negative electrode in Example 2-1, Example 2-2, Example 2-3, or Example 2-4 respectively. A lithium layer with a thickness of 1.0 μm was formed in all of Example 2-5 to Example 2-9.

### C: Formation of Surface Protective Layer

No surface protection layer was formed in Comparative Example 2-0 and Examples 2-1 to 2-9.

### D: Thermal Treatment

No Thermal treatment was implemented in Comparative Example 2-0 and Examples 2-1 to 2-4. Thermal treatments as shown in Table 1 were implemented in Examples 2-5 to 2-9.

Half batteries using the negative electrode of Comparative Example 2-0 and Examples 2-1 to 2-9 were prepared and evaluated in the same manner as Example 1. Results of ICE in Comparative Example 2-0 and Examples 2-1 to 2-9 are shown in Table 1.

Conclusions as follows can be drawn from the results of ICE in Comparative Example 2-0 and Examples 2-1 to 2-9.

ICE in Example 2-2 in which the thickness of the lithium layer formed was 1.0 μm and no thermal treatment was performed was only 72.9%, which is even lower than that of Comparative Example 2-0.

ICE of 105.5% was obtained in Example 2-4 by increasing thickness of the lithium layer to 3.0 μm. This shows that though ICE can be improved by increasing the thickness of the lithium layer, efficiency of pre-lithiation is low.

In contrast to Example 2-2, an ICE value as high as 105.9% or 104.0% was obtained in Example 2-8 or Example 2-9 respectively by a thermal treatment conducted at a heating temperature of 130 C° for 3 min or 10 min even if the thickness of the lithium layer formed was 1.0 μm. This means that an improved efficiency of pre-lithiation has been obtained in Example 2-8 or Example 2-9 as compared with Example 2-2.

In addition, it can be seen from Examples 2-5, 2-6 and 2-7 that when a thickness of the lithium layer was set to 1.0 μm and a heating treatment was carried out at 80° C., ICE can improved by prolonging the time of the thermal treatment. An ICE value of 103.3% was obtained in Example 2-7 by setting the time of the thermal treatment to 20 min.

It is considered that in the case of a negative electrode with a low pressing density, lithium formed on the surface of the electrode is difficult to be diffused into the interior of the electrode (since diffusion coefficient between grains is low) so that lithium is precipitated and deactivated in the holes of the electrode, and thus the pre-lithiation efficiency is reduced. It has been further demonstrated that even for a negative electrode with a low pressing density, the pre-lithiation efficiency can be improved by a heating treatment.

### Example 3

### A: Preparation of Negative Electrode Sheet

Graphite (2) with a press density of 1.285 g/cm³ was used as an active material of the negative electrode.

### B: Formation of Lithium Layer

To be equivalent to other Examples, a lithium layer with a thickness of 0.5 μm, 1.0 μm, or 1.5 μm was formed via evaporation in vacuum of a lithium metal onto the surface of the negative electrode in Examples 3-1 to 3-6, as shown in Table 2 as below.

### C: Formation of Surface Protective Layer

Then, a lithium nitride protective layer of approximately 100 nm was formed in Example 3-1 to Example 3-3 by irradiating the negative electrode obtained in the step B with nitrogen ions.

Besides, a lithium nitride protective layer of approximately 100 nm was also formed in Example 3-4 to Example 3-6 by exposing the negative electrode obtained in the step B to a nitrogen atmosphere of 150 Pa for 10 min.

As a result, a part of the lithium layer was nitrogenized and a 100 nm protective film of Li₃N was formed in Examples 3-1 to 3-6, so that a total thickness of the lithium layer and the lithium nitride protective layer in Examples 3-1 to 3-6 was greater.

### D: Thermal Treatment

A Thermal treatment that was conducted at 130° C. for 10 min in vacuum below 1E-4 Pa was implemented in Examples 3-1 to 3-6.

Half batteries using the negative electrode of Examples 3-1 to 3-6 were prepared and evaluated in the same manner as Example 1. Results of ICE in Examples 3-1 to 3-6 are shown in Table 2.

For comparisons, Comparative Example 2-0, Examples 2-1 to 2-4 and 2-8 to 2-9 that were already present in Table 1 are also listed in Table 2.

It can be concluded from Table 2 that with the surface protective layer being present, ICE can be increased with an increase of thickness of the lithium layer. See Examples 3-1 to 3-3 or Examples 3-4 to 3-6.

Furthermore, it can be seen from Example 2-8, Example 3-2 and Example 3-5 in Table 2 that with the thickness of the lithium layer being the same, the formation of the surface protective layer onto the lithium layer has no significant influence on ICE, which means an equivalent result of ICE can be obtained even if the surface protective layer is formed on the lithium layer.

### Example 4 (Batch Type)

A graphite with a press density of 1.285 g/cm³ was used as an active material of the negative electrode. A lithium layer with a thickness of 0.5 μm, 1.0 μm, or 1.5 μm was formed via vapor deposition onto the surface of the electrode. Then, the lithium layer was irradiated with nitrogen ions (with the pressure being 1E-2 Pa, the discharge voltage being 150 V and the discharge current being 1 A) for 1 min.

### Example 5

### A: Preparation of Negative Electrode Sheet

The negative electrode sheet was prepared by coating the surface of a copper foil as current collector with the following active material slurry, followed by steps of heating, drying and calendaring.

The active material slurry was obtained by mixing SiO/C as an active material, polyacrylic acid (PAA) as a binder, carbon black as a conductivity aid, and distilled water.

SiO/C with a capacity density of 450 mAh/g was used.

The negative electrode obtained has a press density of 1.16 g/cm³.

### B: Formation of Lithium Layer

No lithium layer was formed on the surface of the negative electrode in Comparative Example 5-0. A lithium layer with a thickness of 3.5 μm was formed in Examples 5-1 to 5-3 via evaporation in vacuum of a lithium metal onto the surface of the negative electrode. A lithium layer with a thickness of 4.5 μm or 6 μm was formed in Examples 5-4 to 5-5.

### C: Formation of Surface Protective Layer

No surface protection layer was formed.

### D: Thermal Treatment

Thermal treatments as shown in Table 1 were implemented in Examples 5-1 to 5-5.

Half batteries using the negative electrode of each of Comparative Example 5-0 and Examples 5-1 to 5-5 were prepared and evaluated in the same manner as Example 1. Results of ICE in Comparative Example 5-0 and Examples 5-1 to 5-5 are shown in Table 1.

It can be seen from Comparative Example 5-0 and Examples 5-1 to 5-5 in Table 1 that ICE can be increased by increasing the thickness of the lithium layer, wherein it can be estimated that a thickness of the lithium layer of about 4.8 μm is required to obtain an ICE value of 100%. In addition, efficiency of pre-lithiation in Example 5-1 is low even if a heating treatment at 130° C. for 10 min is carried out.

TABLE 1

| | Conditions | | | | | | | | | |
|---|---|---|---|---|---|---|---|---|---|---|
| | | | | | Surface | | | | | Ideal thickness |
| | Active | | Capacity | Thickness | protection | Thermal treatment | | | | of lithium layer |
| | material of | Press | per unit | of lithium | layer is | Heating | Holding | | | when ICE being |
| | negative | density | of area | layer | present or | temperature | time | OCV | ICE | 100% |
| Examples | electrode | (g/cm³) | (mAh/cm²) | (μm) | not | (° C.) | (min) | (V) | (%) | (μm) |
| Com. Ex. 1-0 | Graphite | 1.609 | 1.7 | 0 | No | — | — | 3.00 | 88.2 | 0.96 |
| Com. Ex. 1-1 | (1) | | | 0.5 | No | — | — | 1.35 | 90.3 | |
| Com. Ex. 1-2 | | | | 1 | No | — | — | 0.31 | 104.2 | |
| Com. Ex. 1-3 | | | | 1.5 | No | — | — | 0.23 | 110.7 | |
| Com. Ex. 1-4 | | | | 1 | No | 80 | 10 | 0.31 | 105.3 | |
| Com. Ex. 1-5 | | | | 1 | No | 130 | 10 | 0.47 | 101.1 | |
| Com. Ex. 2-0 | Graphite | 1.285 | 1.8 | 0 | No | — | — | 3.13 | 89.0 | 0.95 |
| Ex. 2-1 | (2) | | | 0.5 | No | — | — | 1.51 | 86.8 | |
| Ex. 2-2 | | | | 1 | No | — | — | 1.48 | 72.9 | |
| Ex. 2-3 | | | | 1.5 | No | — | — | 0.95 | 82.2 | |
| Ex. 2-4 | | | | 3 | No | — | — | 0.21 | 105.5 | |
| Ex. 2-5 | | | | 1 | No | 80 | 3 | 1.18 | 79.0 | |
| Ex. 2-6 | | | | 1 | No | 80 | 10 | 0.45 | 100.4 | |
| Ex. 2-7 | | | | 1 | No | 80 | 20 | 0.37 | 103.3 | |
| Ex. 2-8 | | | | 1 | No | 130 | 3 | 0.30 | 104.0 | |
| Ex. 2-9 | | | | 1 | No | 130 | 10 | 0.27 | 105.9 | |
| Com. Ex. 5-0 | SiOC | 1.162 | 3.6 | 0 | No | — | — | 3.01 | 85.8 | 2.5 |
| Ex. 5-1 | | | | 3.5 | No | 130 | 10 | 0.84 | 84.9 | |
| Ex. 5-2 | | | | 3.5 | No | 130 | 20 | 0.72 | 87.7 | |
| Ex. 5-3 | | | | 3.5 | No | 130 | 60 | 0.68 | 93.3 | |
| Ex. 5-4 | | | | 4.5 | No | 130 | 10 | 0.69 | 92.4 | |
| Ex. 5-5 | | | | 6 | No | 130 | 10 | 0.36 | 110.1 | |

TABLE 2

| | Conditions | | | | | | | | | |
|---|---|---|---|---|---|---|---|---|---|---|
| | | | | | Surface | | | | | Ideal thickness |
| | Active | | Capacity | Thickness | protection | Thermal treatment | | | | of lithium layer |
| | material of | Press | per unit | of lithium | layer is | Heating | Holding | | | when ICE being |
| | negative | density | of area | layer | present or | temperature | time | OCV | ICE | 100% |
| Examples | electrode | (g/cm³) | (mAh/cm²) | (μm) | not | (° C.) | (min) | (V) | (%) | (μm) |
| Com. Ex. 2-0 | Graphite | 1.285 | 1.8 | 0 | No | — | — | 3.13 | 89.0 | 0.95 |
| Ex. 2-1 | (2) | | | 0.5 | No | — | — | 1.51 | 86.8 | |
| Ex. 2-2 | | | | 1 | No | — | — | 1.48 | 72.9 | |
| Ex. 2-3 | | | | 1.5 | No | — | — | 0.95 | 82.2 | |
| Ex. 2-4 | | | | 3 | No | — | — | 0.21 | 105.5 | |
| Ex. 2-8 | | | | 1 | No | 130 | 3 | 0.30 | 104.0 | |
| Ex. 2-9 | | | | 1 | No | 130 | 10 | 0.27 | 105.9 | |
| Ex. 3-1 | | | | 0.6 | Yes | 130 | 10 | 1.22 | 95.3 | |
| | | | | | (Nitrogen | | | | | |
| | | | | | ion) | | | | | |
| Ex. 3-2 | | | | 1.1 | Yes | 130 | 10 | 0.34 | 101.9 | |
| | | | | | (Nitrogen | | | | | |
| | | | | | ion) | | | | | |
| Ex. 3-3 | | | | 1.6 | Yes | 130 | 10 | 0.22 | 112.7 | |
| | | | | | (Nitrogen | | | | | |
| | | | | | ion) | | | | | |
| Ex. 3-4 | | | | 0.6 | Yes | 130 | 10 | 1.42 | 95.0 | |
| | | | | | (N₂ gas) | | | | | |
| Ex. 3-5 | | | | 1.1 | Yes | 130 | 10 | 0.32 | 103.4 | |
| | | | | | (N₂ gas) | | | | | |
| Ex. 3-6 | | | | 1.6 | Yes | 130 | 10 | 0.22 | 110.1 | |
| | | | | | (N₂ gas) | | | | | |

Certain embodiments and features have been described using a set of numerical upper limits and a set of numerical lower limits. It should be appreciated that ranges including the combination of any two values, e.g., the combination of any lower value with any upper value, the combination of any two lower values, and/or the combination of any two upper values are contemplated unless otherwise indicated. Certain lower limits, upper limits and ranges appear in one or more claims below.

1. A pre-lithiation process comprising:
evaporating lithium onto a surface of a negative electrode to form a lithium layer thereon, and
subjecting the negative electrode to a thermal treatment.

2. The pre-lithiation process of claim 1 wherein the pre-lithiation process further comprises forming a surface protection layer on the lithium layer after forming the lithium layer and before the thermal treatment.

3. The pre-lithiation process of claim 2 wherein the surface protection layer has a thickness of from 20 nm to 2000 nm depending on roughness of surface on which it is formed.

4. The pre-lithiation process of claim 2 wherein the surface protection layer comprises Li₃N.

5. The pre-lithiation process of claim 2 wherein the surface protection layer is formed in a section that maintains a span longer than a main roller when viewed horizontally or vertically, and a conveying speed is from 1 m/min to 20 m/min.

6. The pre-lithiation process of claim 2 wherein the surface protection layer is formed in an atmosphere containing nitrogen gas or by irradiation with nitrogen ions.

7. The pre-lithiation process of claim 1 wherein the thermal treatment is carried out in an annealing room configured with a preheating mechanism and a winding roller with thermal control.

8. The pre-lithiation process of claim 1 wherein the lithium layer has a thickness of 0.5 μm to 10 μm.

9. The pre-lithiation process of claim 1 wherein the lithium layer has a thickness of 0.5 μm to 6 μm.

10. The pre-lithiation process of claim 1 wherein the lithium layer has a thickness of 0.5 μm to 2 μm.

11. The pre-lithiation process of claim 1 wherein an active material in the negative electrode comprises or consists of natural or synthetic graphite, silicon, silicon oxide SiOₓ (0.5≤x≤1.5), or a combination thereof.

12. The pre-lithiation process of claim 1 wherein the thermal treatment is carried out at a temperature of from 80° C. to 130° C. in an atmosphere of rare gas or in an ambient atmosphere.

13. The pre-lithiation process of claim 12 wherein the thermal treatment is maintained at 80° C. for at least 6 minutes when the negative electrode has a press density of 1.3 g/cm³ to 1.6 g/cm³.

14. The pre-lithiation process of claim 12 wherein the thermal treatment is maintained at 130° C. for at least 90 minutes when the negative electrode has a press density of 1.0 to 1.3 g/cm³.

15. An equipment for implementing the pre-lithiation process of claim 6.

16. An equipment for implementing the pre-lithiation process of claim 7.

17. An equipment for implementing the pre-lithiation process of claim 12.
